(19) United States
(12) Patent Application Publication
(10) Pub. No.: US 2006/0043396 A1
(43) Pub. Date: Mar. 2, 2006

(54) Sapphire substrate, epitaxial substrate and semiconductor device

(75) Inventors: Michinobu Tsuda, Higashioumi-shi (JP); Masataka Imura, Obu-shi (JP); Akira Honshio, Toyota-shi (JP); Motoaki Iwaya, Inazawa-shi (JP); Satoshi Kamiyama, Nagoya-shi (JP); Hiroshi Amano, Nagoya-shi (JP); Isamu Akasaki, Nagoya-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/215,406

(22) Filed: Aug. 29, 2005

(30) Foreign Application Priority Data
Aug. 30, 2004 (JP) 2004-250091
Apr. 26, 2005 (JP) 2005-128330

(51) Int. Cl. H01L 29/22

(52) U.S. Cl. 257/94

(57) ABSTRACT

An epitaxial substrate for manufacturing field effect transistor (FET) that has heterojunction structure consisting of at least a channel layer made of gallium nitride or gallium indium nitride and a barrier layer made of aluminum gallium nitride formed successively on the principal plane of the sapphire substrate, wherein the principal plane of the sapphire substrate semiconductor is inclined from (01-12) plane toward (0001) plane by an off-angle α that is in a range of 0°<x≦5°. With this constitution, an epitaxial substrate for manufacturing field effect transistor having high smoothness is provided.

### BACKGROUND OF THE INVENTION

1. Field of the Invention

The present invention relates to a sapphire substrate for growing a nitride semiconductor thereon, and an epitaxial substrate and a semiconductor device that utilize the same.

2. Description of Related Art

Nitride semiconductors such as aluminum nitride (AlN), gallium nitride (GaN), indium nitride (InN) or aluminum indium gallium nitride (AlₓGa_{1-x-y}In_{y}N(0≦x≦1, 0≦y≦1, 0≦x+y≦1)) that is a mixed crystal of the former ones, can be applied to light emitting or sensing device and electron device, and therefore have been widely studied in researches on the crystal growth and application to semiconductor devices. Some applications thereof to light emitting diode and laser diode have already been commercialized.

Since nitride semiconductor cannot be grown into a large bulk of single crystal, it is usually hetero-epitaxially grown on a semiconductor growing substrate made of a different material such as (0001) sapphire (hereinafter referred to as C-plane sapphire), (11-20) sapphire, (0001) 4H—SiC or (0001) 6H—SiC.

Epitaxial growth techniques include metalorganic vapor phase epitaxy (MOVPE) method, molecular beam epitaxy (MBE) method, halide vapor phase epitaxy (HVPE) method and other, of which the MOVPE method is most commonly employed for its practical usefulness.

Semiconductor devices such as light emitting devices and electron devices that use the semiconductors such as those described above are manufactured by forming a structure where nitride semiconductor layers placed one on another by epitaxial growth over the entire surface of a sapphire substrate, processing the nitride semiconductor layers to form the device of desired configuration and forming electrodes thereon.

The nitride semiconductors that have been used in commercialized semiconductor devices have high levels of piezoelectricity due to wurtzite structure of hexagonal system that does not have inversion symmetry. FIG. 17 shows a heterojunction of a nitride semiconductor consisting of two layers (a first layer 91 and a second layer 92) formed from different materials one on another, where crystal growth is entirely oriented such that an interface 91a of the heterojunction is perpendicular to C axis 93, which is referred to as C axis orientation. When a heterojunction is made by forming two layers that have different lattice constants one on another, therefore, a high piezoelectric field is generated due to a strain in the crystal.

The piezoelectric field has a significant influence on the characteristics of the semiconductor device, which will be discussed in the following description in the case of light emitting diode and laser diode.

Japanese Unexamined Patent Publication (Kokai) No. 11-177175 discloses a device made by forming an n-type buffer layer 103, an n-type cladding layer 104, an n-type guide layer 105, an active layer of quantum well structure 106, a p-type cap layer 107, a p-type guide layer 108, a p-type cladding layer 109 and a p-side contact layer 110 successively on a substrate prepared by forming a GaN layer 102 on a C-plane sapphire substrate 101 as shown in FIG. 18. Then the n-type cladding layer 104 and the p-type cladding layer 109 are exposed by dry etching, whereon an insulation layer 111, a p-type electrode 112 and an n-type electrode 113 are formed so as to constitute a laser diode 135. The active layer 106 is typically formed in quantum well structure as described above, which results in a change in energy band structure due to the strong piezoelectric field, leading to a problem with respect to improvement of characteristics.

In the case of a laser diode made by using other compound such as aluminum gallium arsenide, quantum well structure is intentionally strained so as to improve the characteristics such as lowering the threshold current of the laser through modification of the energy band structure of the semiconductor. However, in the nitride semiconductors that are used at present, a decrease in the threshold current of the laser can hardly be achieved by intentionally generating a strain. This is because the crystal has C axis orientation with respect to the direction of growth of the nitride semiconductor, and therefore the energy band structure does not change effectively.

In the case of a light emitting diode, too, the piezoelectric field generated in the active layer decreases the probability of carrier recombination, thus hindering the improvement of luminance.

Now an application to an electron device such as field effect transistor (hereinafter referred to as FET) will be described below. Normally heterojunction of GaN and aluminum gallium nitride (hereinafter referred to as AlGaN) is used so as to generate two dimensional electron gas in the interface thereof.

For example, Japanese Unexamined Patent Publication (Kokai) No. 10-335637 describes formation of an FET as shown in FIG. 19. First, an undoped GaN layer 115 having thickness of 2 μm is grown, via a low temperature buffer layer 114 having thickness of 30 nm, on the C-plane sapphire substrate 101, followed by successive formation of an undoped Al_{0.3}Ga_{0.7}N layer 116 having thickness of 30 nm, an undoped GaN layer 117 having thickness of 10 nm, an undoped Al_{0.3}Ga_{0.7}N spacer layer 118 having thickness of 10 nm, an n-type Al_{0.3}Ga_{0.7}N electron supplier layer 119 having thickness of 10 nm, an undoped AlₓGa₁₋ₓN barrier layer 120 having graded composition and thickness of 15 nm and an n-type Al_{0.06}Ga_{0.94}N contact layer 121 having thickness of 6 nm. Then a source electrode 122, a drain electrode 123 and a gate electrode 124 are formed thereby to obtain an FET 136.

When the nitride semiconductor is grown on the C-plane sapphire substrate 101, the nitride semiconductor having C axis orientation is obtained wherein an inversion layer is formed near the interface of the heterojunction under the influence of the piezoelectric field that is characteristic of the material, so that two dimensional electron gas having density of about 10¹³ cm⁻² is formed in the interface even when no impurity is added. Therefore, the FET 11 made from this semiconductor becomes a so-called depression type FET where drain current can flow when the gate bias is zero.

In practice, however, not only the depression type FET but also a so-called enhancement type FET, where drain current cannot flow when the gate bias is zero but flows as the gate bias is applied, are needed.

However, as the enhancement type FET made of nitride semiconductor is not available at present and there are many restrictions on the design of circuit placing limitations on the applications thereof, there has been a strong demand for the enhancement type FET made of nitride semiconductor.

In order to manufacture the enhancement type FET, it is necessary to control the formation of the inversion layer in the nitride semiconductor layer structure.

In an FET made of an arsenide semiconductor, for example, formation of the inversion layer can be controlled by keeping the thickness of a barrier layer formed from aluminum gallium arsenide within several tens of nanometers, thus making it possible to selectively manufacture the depression type and the enhancement type FETs.

While the design of a circuit may require the depression type FET, which needs two power supplies of positive and negate voltages in order to operate, it results in such problems as increased power consumption and larger number of components in the circuit that uses it.

As described above, the piezoelectric field of the nitride semiconductor has a significant influence on the characteristics of the semiconductor device. Japanese Journal of Applied Physics, Vol. 39 (2000), pp 413-416 reports a method for growing crystal that is free from the problem of piezoelectric field, which is accomplished through (11-20) orientation (hereinafter referred to as A axis orientation) or (10-10) orientation.

While there is no effective way to grow a nitride semiconductor with (10-10) orientation, Japanese Journal of Applied Physics, Vol. 42 (2003), L818-L820 describes a method of using (01-12) sapphire substrate (hereinafter referred to as R-plane sapphire substrate) and Applied Physics Letters, Vol. 83 (2003), pp 5208-5210 describes a method of growing AlN on 4H—SiC (11-20) substrate, for growing a nitride semiconductor with (10-20) orientation. Among these, the latter is not practical since it is difficult to obtain large 4H—SiC (11-20) substrate with the current manufacturing techniques and the method is not suited for volume production. The R-plane sapphire substrate, in contrast, can be manufactured to a size of 8 inches at present, thus eliminating the problem of substrate size. In addition, this method is very promising for industrial applications, since it can be carried out in a semiconductor device manufacturing process similar to that of manufacturing silicon-based semiconductor devices, and it can be applied in combination with an SOS (silicon-on-sapphire) device. Accordingly, it is considered to be most advantageous to employ the method of growing the nitride semiconductor on R-plane sapphire substrate, from the view point of volume production and manufacturing cost.

Through researches conducted by the inventors of the present application and others, it has been found that growing the nitride semiconductor on R-plane sapphire substrate has such problems that much threading dislocations and stacking faults are introduced into the crystal due to a large difference in the lattice constant and non-polarity of sapphire, and that unfavorable form of crystal is involved that makes it difficult to form a steep interface that is required to manufacture the semiconductor device.

As the means for reducing the density of threading dislocations, in has been reported in Applied Physics Letters, Vol. 84 (2004), pp 3663-3665 to increase the thickness of the GaN layer. As shown in FIG. 20, an n-type GaN layer 125 having thickness of 30 μm, an n-type Al_{0.1}Ga_{0.9}N cladding layer 126, a GaN/In_{0.15}Ga_{0.85}N active layer of multiple quantum well structure 127, a p-type Al_{0.1}Ga_{0.9}N cladding layer 128 and a p-type GaN layer 129 are formed successively on the R-plane sapphire substrate 11 by the MOVPE method. Then the n-type GaN layer 125 is exposed by dry etching, whereon a p-side electrode 130 and an n-side electrode 131 are formed, thereby to obtain the light emitting diode 137.

Another method of reducing the density of threading dislocations that utilizes selective growth in lateral direction is described in Applied Physics Letters, Vol. 81 (2002), pp 1201-1203. As shown in FIG. 21, after growing a GaN layer 132 by the MOVPE method on the R-plane sapphire substrate 11, a mask 133 is formed from SiO₂ by known techniques of photolithography and wet etching, followed by regrowth of GaN layer 134 by the MOVPE method. With this method, the mask 133 prevents the threading dislocations from propagating to the regrowth layer, thus reducing the density of threading dislocations.

Although the method described in Applied Physics Letters, Vol. 84 (2004), pp 3663-3665 is useful in that consideration is given to the piezoelectric field in the active layer 127, it is not suited for practical applications because of such problems as the n-type GaN layer 125 having thickness of 30 μm that is too thick to constitute a light emitting diode is used resulting in too long a time taken to grow, and the epitaxial substrate undergoes significant warping after growing. These problems stem from the fact that the nitride semiconductor is grown to a large thickness to obtain a smooth surface, since the surface tends to be rough when the thickness is small.

While surface smoothness of the light emitting device structure is an important factor in the manufacture of a light emitting device, it has been difficult to form a smooth surface in a light emitting device structure having film thickness of several micrometers that is suitable for. practical application.

The method described in Applied Physics Letters, Vol. 81 (2002), pp 1201-1203 has such a problem that a significant length of regrowth time is required before the crystal of the regrown GaN layer 134 grows laterally on the mask and meets the adjacent regrown GaN layer 134 thereby to form a smooth surface, while the crystal grows in the direction of thickness as well as in the lateral direction, thus resulting in a large total thickness of the GaN layers. Moreover, the threading dislocations inevitably propagates from the portion of the surface of the regrown GaN layer 134 that is not selectively masked, thus making it difficult to decrease the density of threading dislocations over the entire substrate surface. In addition, since SiO₂ of the mask 133 is embedded in the regrown GaN layer 134, unintended diffusion of silicon from the mask 133 may cause deterioration in the electric characteristic of the semiconductor device.

In case nitride semiconductor layers are formed on (01-12)-plane sapphire substrate by the conventional low temperature buffer layer technique, there has been such a problem that smooth base layer cannot be formed due to the small film thickness, thus making the method unsuited for the manufacture of semiconductor devices. In order to solve this problem, for example, Japanese Unexamined Patent Publication (Kokai) No. 2002-374003 proposed a method of growing crystal so that C axis of the stacked layer structure becomes parallel to the semiconductor growing substrate, by using the (01-12) plane oriented sapphire substrate, although no mention is made to the smoothness of the surface of the stacked layer structure. Japanese Unexamined Patent Publication (Kokai) No. 2002-374003 also does not discuss the operation of the FET made by employing this method of crystal growth.

Despite the fact that surface smoothness is a very important factor in the manufacture of the FET, smooth surface can hardly be obtained even when the stacked layer structure is formed by using the (01-12) plane oriented sapphire substrate, and it is difficult to obtain the FET through the use thereof.

### SUMMARY OF THE INVENTION

According to the present invention, an epitaxial substrate for manufacturing an FET having high smoothness is provided by optimizing the off-angle of the principal plane of the sapphire substrate and the growing conditions of the stacked semiconductor layer structure.

Moreover, according to the present invention, an A axis oriented nitride semiconductor having low density of threading dislocations and high surface smoothness can be formed with a small thickness over the entire surface of the R-plane sapphire substrate. This makes it possible to provide an epitaxial substrate that enables it to manufacture semiconductor devices of high performance such as light emitting diode, laser diode and transistor.

(1) Principal plane of the sapphire substrate of the present invention where the nitride semiconductor is grown is such that the off-angle α of inclination thereof from (01-12) plane toward (0001) plane is in a range of 0°<x≦5°.

The epitaxial substrate of the present invention that uses this sapphire substrate is used in the manufacture of field effect transistor, where the nitride semiconductor layers are stacked on the principal plane of the sapphire substrate. The stacked layer structure has heterojunction structure consisting of at least a channel layer made of gallium nitride or gallium indium nitride, and a barrier layer made of aluminum gallium nitride formed one on another.

The epitaxial substrate described above is preferably used to make a semiconductor device. Particularly it is made possible to manufacture an FET that makes enhancement type operation, since the epitaxial substrate based on nitride semiconductor is provided.

(2) Another epitaxial substrate of the present invention comprises a sapphire substrate having the principal plane in the (01-12) plane and at least first and second layers made of nitride semiconductors of different compositions formed in this order on the substrate, wherein a sectional plane in the top surface of the first layer has surface irregularity of 10 nm to 20 μm in period and 10 nm to 10 μm in height, while the top surface of the second layer has root mean square surface roughness (RMS) of less than 10 nm. The epitaxial substrate described above is preferably used to make a semiconductor device.

A method of manufacturing the epitaxial substrate described above includes the steps of growing the first layer on the sapphire substrate so that the lower surface of the first layer receives a strain caused by lattice mismatch directly or indirectly from the sapphire substrate, thereby to give the sectional plane in the top surface of the first layer surface irregularity of 10 nm to 20 μm in period and 10 nm to 10 μm in height, and growing the second layer on the first layer, that are carried out in this order.

Another method of manufacturing the epitaxial substrate described above includes the steps of growing the first layer on the sapphire substrate that has the principal plane on R plane, treating the sectional plane in the top surface of the first layer to have surface irregularity of 10 nm to 20 μm in period and 10 nm to 10 μm in height, and forming the second layer on the first layer by regrowing, that are carried out in this order.

This enables it to manufacture the epitaxial substrate having an A axis-oriented nitride semiconductor that has a reduced density of threading dislocations, a reduced density of stacking faults and high surface smoothness, with small film thickness. As a result, the problem caused by the piezoelectric field in the semiconductor device can be solved so as to provide a semiconductor device of high performance and enable it to manufacture FET that makes enhancement type operation.

(3) The sapphire substrate of the present invention has the principal plane inclined from (01-12) plane toward (0001) plane by an off-angle of α that is in a range of −0.75°≦α≦−0.25°. Or, alternatively, another sapphire substrate of the present invention has the principal plane inclined from (01-12) plane toward (0001) plane by an off-angle of α and, at the same time, is inclined by an off-angle of β in a direction perpendicular to this direction, the angles being in ranges of −0.75°≦α≦−0.25° and 0°≦|β|≦0.05°.

The light emitting device of the present invention that employs the sapphire substrate described above comprises the sapphire substrate and a light emitting device structure formed on the principal plane of the sapphire substrate. The light emitting device structure is made of nitride semiconductor represented by AlₓGa_{1-x-y}In_{y}N (0≦x, 0≦y, x+y≦1), and includes at least an n-type cladding layer, an active layer and a p-type cladding layer.

With this constitution, a high efficiency light emitting device can be manufactured stably, with the surface smoothed without being affected by the variations in the light emitting device structure. It is also made possible to reduce the time required for growing the light emitting device structure, thereby to reduce the cost. Also because there occurs no significant warping even when the light emitting device structure is formed on a large substrate, the constitution is suitable for volume production of the light emitting device.

### BRIEF DESCRIPTION OF THE DRAWINGS

FIG. 1 is a sectional view showing an epitaxial substrate according to a first embodiment of the present invention.

FIG. 2 is a sectional view showing the relation between the crystal orientations of a substrate and a stacked structure of the epitaxial substrate.

FIG. 3 is a sectional view showing a semiconductor device according to the first embodiment of the present invention.

FIG. 4 is a sectional view showing an epitaxial substrate according to a second embodiment of the present invention.

FIG. 5 is a sectional view showing another epitaxial substrate according to the second embodiment of the present invention.

FIG. 6 is a schematic diagram showing the crystal orientation of R-plane sapphire substrate.

FIG. 7 is a sectional view showing the crystal orientation of a sapphire substrate according to a third embodiment of the present invention.

FIG. 8 is a sectional view showing the crystal orientation of the sapphire substrate according to the third embodiment.

FIG. 9 is a perspective view showing the crystal orientation of the sapphire substrate.

FIG. 10 is a sectional view showing a light emitting device according to the third embodiment.

FIG. 11 is a transmission electron microscope photograph of an epitaxial substrate made in Example III.

FIG. 12 is an atomic force microscope photograph of the epitaxial substrate made in Example III.

FIG. 13 is a sectional view showing the semiconductor device (light emitting diode) according to the second embodiment.

FIG. 14 is a sectional view showing the semiconductor device (laser diode) according to the second embodiment.

FIG. 15 is a sectional view showing the semiconductor device (field effect transistor) according to the second embodiment.

FIG. 16 is a sectional view showing the light emitting device of Example XI according to the third embodiment.

FIG. 17 is a schematic diagram showing a heterojunction of nitride semiconductor having crystal orientation in C axis.

FIG. 18 is a sectional view showing a laser diode of the prior art.

FIG. 19 is a sectional view showing the semiconductor device (field effect transistor) of the prior art.

FIG. 20 is a sectional view showing the semiconductor device (light emitting diode) of the prior art.

FIG. 21 is a sectional view showing a method of reducing the density of threading dislocations of the prior art.

### DESCRIPTION OF PREFERRED EMBODIMENTS

### First Embodiment

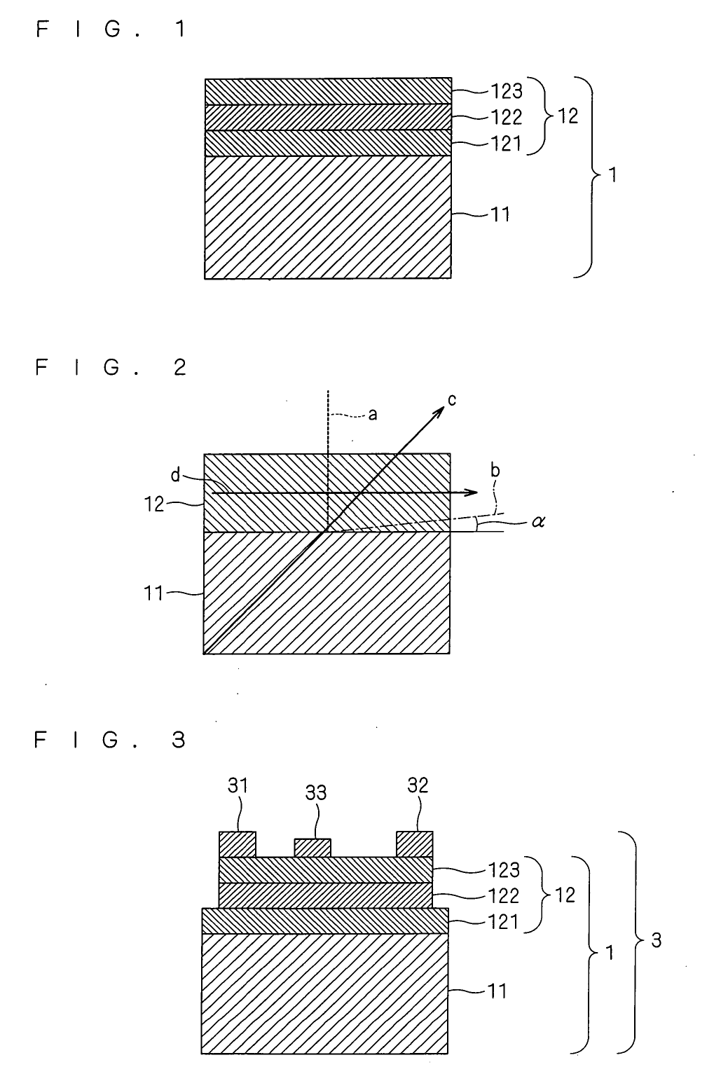

FIG. 1 is a schematic sectional view showing an epitaxial substrate according to this embodiment. As shown in FIG. 1, the epitaxial substrate 1 has a stacked layers structure 12 comprising a base layer 121, a channel layer 122 and a barrier layer 123 formed successively on one of the principal surfaces of a semiconductor growing substrate 11 made of sapphire. The base layer 121 is formed from aluminum gallium nitride where molar ratio x of AlN is in a range of 0.5≦x≦1.0. The channel layer 122 is formed from GaN or GaInN. The barrier layer 123 is formed from AlGaN.

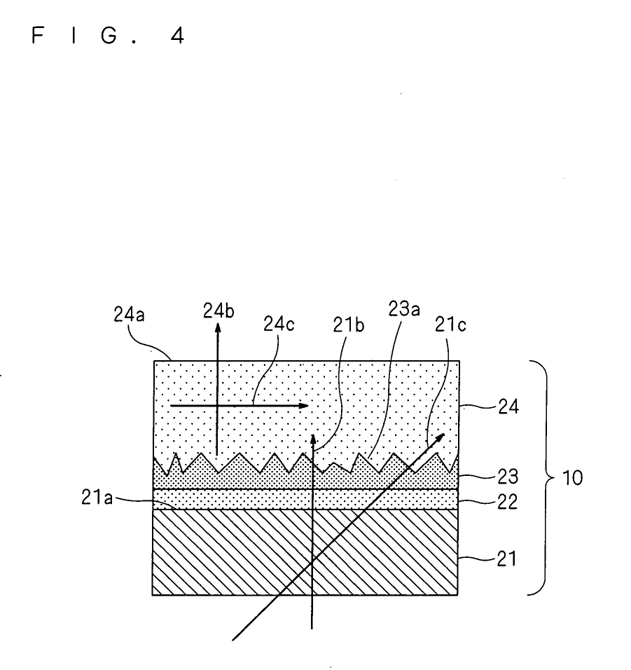

The stacked layers structure 12 made of nitride semiconductor is formed so that [0001] axis (denoted as d in FIG. 2, hereinafter referred to as C axis) is oriented parallel to the principal plane of the semiconductor growing substrate 11.

As shown in FIG. 2, the angle between one principal plane of the semiconductor growing substrate 11 and (01-12) plane of sapphire (denoted as “b” in FIG. 2) is the off-angle α of the principal plane of the semiconductor growing substrate 11. c axis (denoted as “c” in the figure) of the semiconductor growing substrate 11 is inclined from the principal plane. A sapphire substrate having the principal plane inclined with an off-angle of 0°<α≦0.5° is particularly preferable since it is easy to grow the stacked layers structure 12 comprising the base layer 121, the channel layer 122 and the barrier layer 123 on the sapphire substrate with the C axis (denoted as “d” in FIG. 2) lying parallel to the principal surface.

In order to achieve this constitution, it is preferable to set the molar ratio x of AlN in AlGaN that constitutes the base layer 121 in a range from 0.5 to 1.0 and thickness thereof in a range from 0.05 to 2.0 μm.

In case the off-angle α is 0° or larger than 5°, such problems arise as C axis of the stacked layers structure cannot be made parallel to the principal plane, or it becomes difficult to grow the layer with smooth surface. Similar problems occur when the principal plane is oriented with an off-angle toward the (01-12) plane.

When the base layer 121 is formed thicker than 2 μm, cracks tend to occur. When the base layer 121 is formed thinner than 0.05 μm, it is difficult to grow the layer with smooth surface.

Arithmetic mean surface roughness of the nitride semiconductor layer 12 formed by epitaxial growth may be measured with an atomic force microscope (AFM). Surface roughness must be 10 nm or less in terms of root mean square surface roughness Rrms.

According to the present invention, it is made possible to grow the layer with smooth surface on the above-mentioned sapphire substrate and make the FET 3 enhancement type, since C axis of the stacked layers structure 12 is oriented within the plane of the stacked layers structure 12 so that piezoelectric field will not be generated in the direction perpendicular to the stacked layers structure 12.

Even when the layer can be grown with smooth surface, the stacked layers structure 12 is subject to cracks unless the base layer 121 is grown while controlling the thickness and composition as in the present invention.

While the channel layer 122 formed from GaN or GaInN must not be doped with an impurity in order to maintain high mobility of electron, the layer thickness may be in a range from 10 to 200 nm.

When GaInN is used in the channel layer 122, high molar ratio of InN increases the density of two-dimensional electron gas in the stacked layers structure 12, although the electron mobility is likely to decrease due to diffusion of alloy. Thus molar ratio of InN is preferably set to 0.1 or lower as required.

Then the barrier layer 123 is formed from AlGaN. Thickness of the barrier layer 123 is set in a range from 5 to 50 nm, and two-dimensional electron gas is formed in the interface between the channel layer 122 and the barrier layer 123 (when forming the inversion layer).

The barrier layer 123 may also be subjected to modulated doping, so as to form an undoped spacer (not shown) for the purpose of improving the electron mobility of the FET and an electron feeding layer (not shown) doped with silicon for the purpose of supplying electron.

The channel layer 122 and the barrier layer 123 grown on the base layer 121 must be formed from crystal coherent with the principal plane of the base layer 121.

Also a contact layer (not shown) having high silicon density may be grown to a thickness from 3 to 20 nm on the barrier layer 123, for the purpose of providing satisfactory ohmic contact between a source electrode 31 and a drain electrode 32.

Growing temperatures of the layers may be set so as not to affect the characteristics of the epitaxial substrate 1 such as composition, crystallinity, surface roughness and electric properties.

The sapphire substrate 12 has an advantage of low price, and allows it to manufacture the epitaxial substrate 1 at a lower cost compared to a case of using sapphire that has the principal plane in other typical directions of crystal plane such as C plane or (11-20) plane.

Now an FET made by using the epitaxial substrate described above will be described. As shown in FIG. 3, the FET 3 is constituted from the epitaxial substrate 1, the source electrode 31, the drain electrode 32 and the gate electrode 33.

The FET 3 may be manufactured by the known technique of photolithography, vapor deposition or etching.

Isolation of the devices may be done by processing of mesa as shown in FIG. 3 through wet etching, dry etching or the like, or by partially increasing the resistance through selective thermal oxidation or ion implantation.

Satisfactory ohmic contact between the source electrode 31 and the drain electrode 32 can be formed by forming the electrodes from Ti/Al/Ti and applying heat treatment at a temperature from 600 to 1000° C. The gate electrode 33 is made by forming Ni/Au layers so as to form a schottky junction.

Last, pad electrodes are formed from Ti/Au for the source, drain and gate electrodes, thus completing the FET 3.

The FET 3 manufactured as described above is the so-called enhancement type that allows drain current to flow when gate bias is applied.

### Second Embodiment

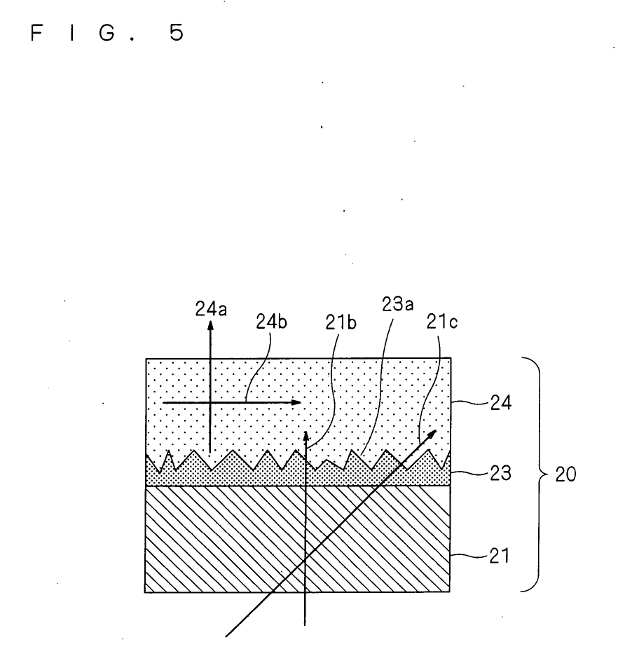

FIG. 4 is a sectional view showing an epitaxial substrate according to a second embodiment of the present invention. This epitaxial substrate is manufactured by forming a base layer 22 and a first layer 23 successively on a principal plane 21a of the sapphire substrate 21 that has the principal plane on (01-12) plane (hereinafter referred to as R-plane sapphire substrate 21) by the MOVPE method. The first layer 23 receives a strain from the base layer 22, and therefore has the sectional plane thereof spontaneously generating irregular surface configuration 23a having period in a range from 10 nm to 20 μm and height in a range from 10 nm to 10 μm during crystal growth. Then a second layer 24 is grown so as to make the irregular surface configuration 23a formed on the first layer 23 smooth. As a result, root mean square surface roughness (hereinafter RMS) of the surface 24a of the second layer 24 becomes less than 10 nm. In case the irregular surface configuration 23a is not smoothed, the photolithography process that follows is affected and the semiconductor device cannot be manufactured.

The (01-12) plane (R plane) of the sapphire substrate is a plane perpendicular to R axis, the (0001) plane (C plane) of the sapphire substrate is a plane perpendicular to C axis, and (11-20) plane (A plane) of the sapphire substrate is a plane perpendicular to A axis. The (01-12) plane in this specification refers to a plane that has an off-angle within±5 degrees except for 0 degree.

It is important that the irregular surface configuration 23a of 10 nm to 20 μm in period and 10 nm to 10 μm in height is formed on the first layer 23. This causes crystalline defects such as density of threading dislocations and density of stacking faults to deflect sideways so as to be prevented from propagating in the direction of thickness when the second layer 24 is formed, thereby making it possible to reduce the density of crystalline defects in the surface 14a of the epitaxial substrate.

Reference numerals 21b and 21c in FIG. 4 denote R axis and C axis of the R-plane sapphire substrate 21, respectively. Reference numerals 24b and 24c denote A axis and C axis of the second layer 24, respectively.

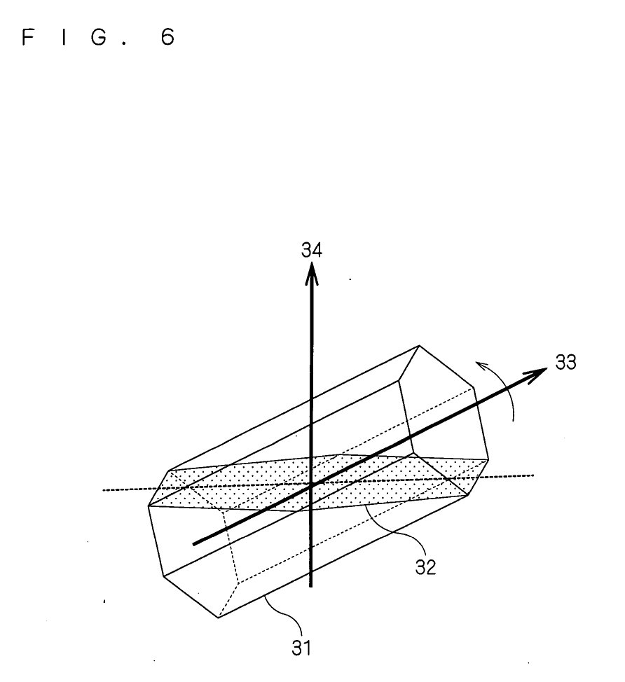

The off-angle of the principal plane 32 of the R-plane sapphire substrate 21 used in the present invention is preferably about 0.5 degrees in such a direction as the C axis 33 approaches the R axis 34 as shown in FIG. 6, which makes it easier to grow the crystal. However, the effects of the present invention can be achieved by controlling the growing conditions in case the off-angle is within±5 degrees in every direction. According to the present invention, the off-angle is not limited to 0.5 degree in the direction of inclining the C axis 33 toward the R axis 34. Reference numeral 31 in FIG. 6 denotes a unit cell of the R-plane sapphire substrate 21.

Similar effects can be achieved also by employing other method of growing crystal such as MBE or HVPE, instead of the MOVPE method.

In case the second layer 24 is formed from GaN, it can also serve as the bottom layer of the semiconductor device when forming the semiconductor device thereon, and it may be an n-type cladding layer of a blue laser diode or a blue light emitting diode, or a channel layer of an FET.

In case the second layer 24 is formed from a material other than GaN, another layer may be formed from GaN on the epitaxial layer. Of course, the invention is not restricted to this constitution in case the semiconductor device is formed without using GaN, such as an ultraviolet ray emitting diode.

While thickness of the second layer 24 is preferably in a range from 1 nm to 10 μm for the convenience of manufacturing the semiconductor device, the effect of the present invention can be achieved even when thickness of the layer is larger or smaller than this range. The irregular surface configuration 23a formed to be more than 10 μm in height deviates from the purpose of achieving the layer with a small thickness, and is not preferable.

The epitaxial substrate of the present invention is characterized in that the density of crystalline defects can be reduced with a small layer thickness. The semiconductor device having high performance can be manufactured by using the epitaxial substrate having the semiconductor device structure including the light emitting and receiving devices or electron device on the second layer 24.

Nitride semiconductors AlₓGa_{1-x-y}In_{y}N (0≦x≦1, 0≦y≦1, 0≦x+y≦1) that have different lattice constants can be grown by varying the values of x and y. Accordingly, the extent of strain can be controlled by stacking nitride semiconductor layers of different compositions one on another. This is based on the fact that stacking of the nitride semiconductor layers of different compositions one on another leads to the generation of strain due to lattice mismatch and the strain influences the crystallinity.

The crystallinity of the irregular surface configuration 23a described above can be obtained by putting the lattice of the nitride semiconductor that constitutes the first layer 23 under the influence of the strain. This can be achieved by forming the layers one on another while controlling flow rate of the stock material gas and growing conditions such as temperature and pressure. That is, the base layer 22 may be grown on the R-plane sapphire substrate 21 so that the bottom end of the first layer 23 receives the strain from the base layer 22, as shown in FIG. 5. Or, alternatively, such a constitution may also be employed as the first layer 23 receives the strain directly from the R-plane sapphire substrate 21 without growing the base layer 22, as shown in FIG. 5.

In case the base layer 22 is formed from AlN (x=1, y=0) on the R-plane sapphire substrate 21, and the first layer 23 is formed from Al_{0.5}Ga_{0.5}N (x=0.5, y=0) on the base layer 22 in FIG. 4, for example, the first layer 23 that has a lattice constant larger than that of the base layer 22 receives compressive strain from the base layer 22, thus making it easier to grow the first layer 23 of the crystallinity of the irregular surface configuration 23a.

In case the strains is applied from the R-plane sapphire substrate 21 to the first layer 23 made of AlN (x=1, y=0) in FIG. 5, for example, while the crystalline structures do not match, interatomic distance of the R-plane sapphire substrate 21 on the surface thereof is larger than that of the first layer 23 that is oriented in the A axis, and therefore the first layer 23 receives monoaxial strain so that it is made easier to grow the first layer 23 of the crystallinity of the irregular surface configuration 23a.

Thus whichever values of x and y are chosen, the threading dislocations and the stacking faults in the second layer can be deflected and are hence prevented from propagating to the surface of the epitaxial substrate 10 or 20, thereby to obtain high quality crystal. However, when the growing conditions of the second layer are not controlled, section of the second layer also becomes an irregular surface that is not suitable for the epitaxial substrate, and it may become difficult to form a satisfactory semiconductor device. Thus it is preferable to control the growing conditions of the second layer. Specifically, irregularity of the first layer 23 can be filled in to obtain a smooth surface by controlling the ratio of supplying the group V material and the group III material (the so-called V/III ratio) in a range from 5 to 900 and controlling the growing temperature in a range from 700 to 1050° C. It should be noted that, even when such growing conditions are employed, irregularity 23a of the first layer 23 cannot be filled in and the surface is not smoothed, when the duration of growing is not sufficiently long. However, when the growing conditions are controlled as described above, the surface of the epitaxial substrate 10 or 20 can be smoothed without forming layers as thick as 30 μm as in the case of the prior art.

The first layer 23 may be formed either by crystal growth such that the surface irregularity from 10 nm to 20 μm in period and from 10 nm to 10 μm in height is achieved, or the first layer 23 that has been formed without irregularity may be processed so as to intentionally form the irregularity 23a. To process the first layer 23 intentionally, known technique of photolithography, etching or vapor deposition is preferably employed.

When period of irregularity is smaller than 10 nm, the effect of deflecting the threading dislocations and the stacking faults sideways in the second layer is not achieved sufficiently, and crystal quality cannot be improved. When period of irregularity is larger than 20 μm, it becomes difficult to fill in the irregularity of the first layer with the second layer and smooth the surface. As to the height of the irregularity of the first layer, crystal quality of the second layer cannot be improved when the height of irregularity is smaller than 10 nm, and it becomes difficult to smooth the surface when the height of irregularity is larger than 10 μm.

When the irregularity 23a is formed while growing, time required to manufacture the epitaxial substrate 10 or 20 can be reduced by, after growing the first layer 23, growing the second layer 24 thereon without taking it out of the semiconductor growing apparatus.

In case the second layer 24 is grown after growing the first layer 23 and taking it out of the semiconductor growing apparatus, the time required to manufacture the epitaxial substrate becomes longer but the condition of the irregularity 23a of the first layer 23 can be checked so as to control the rowing conditions of the second layer 24 accordingly.

### Third Embodiment

FIG. 7 is a sectional view along the (11-20) plane that is the A plane of a sapphire substrate 35 of this embodiment. Accordingly, [0001] (denoted as c in the figure), that is the C axis, is inclined from the principal plane 36 of the sapphire substrate 35. The sapphire substrate 35 of the present invention has the principal plane 36, that is the R plane, inclined from (01-12) plane toward (0001) plane.

Definition of the off-angle α of inclining the (01-12) plane toward (0001) plane in the present invention is as follows. Off-angle α is the angle between the principal plane 36 of the sapphire substrate 35 and the (01-12) plane of sapphire. Since [0001] of sapphire which has hexagonal crystal system is uniquely determined, an Off-angle of the (01-12) plane approaching (0001) as denoted by “a” in the figure is defined as positive. On the other hand, an Off-angle of the (01-12) plane moving away from (0001) as denoted by “a′” in the figure is defined as negative.

The off-angle α satisfies the relation −0.75°≦α≦−0.25°. The reason for setting the off-angle α within the range described above is that an angle out this range may result in lower surface smoothness of the crystal grown on the principal plane 36 of the sapphire substrate 11.

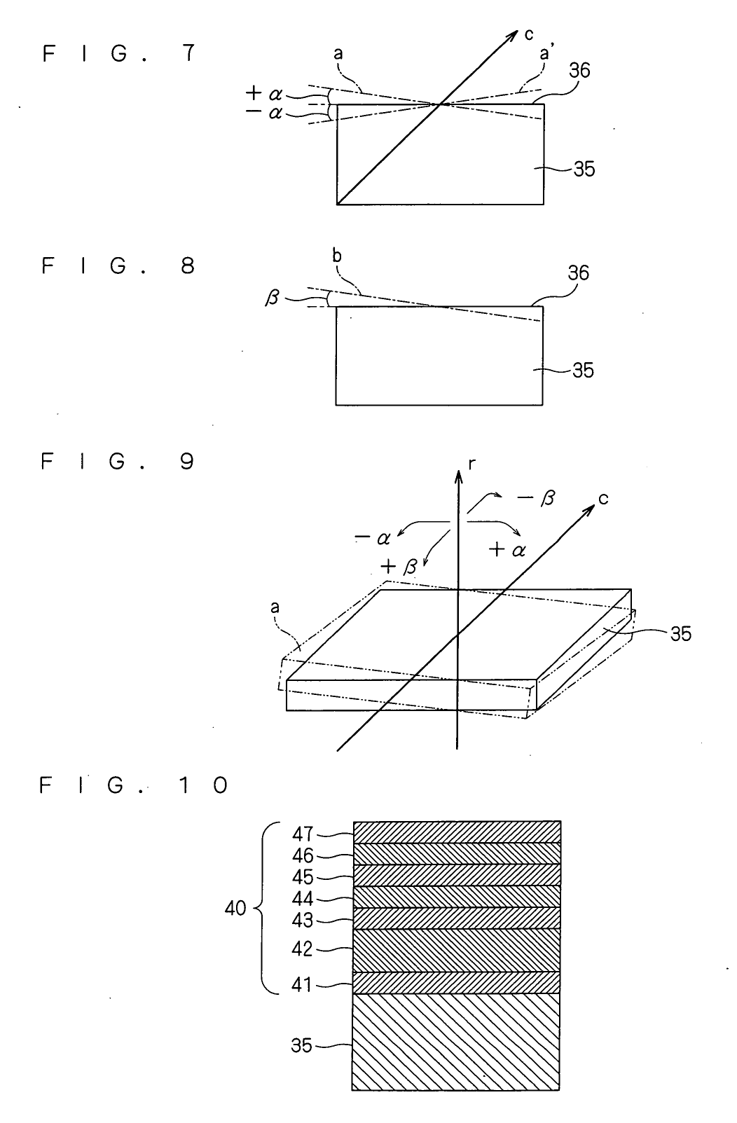

FIG. 8 shows a sectional view along a plane perpendicular to the (11-20) plane of the sapphire substrate 35 of the present invention. In this case, [0001] of the sapphire substrate cannot be shown in the figure. In the sectional view, off-angle β is defined for the inclination of the (01-12) plane in a direction perpendicular to the off-angle α. While off-angle β is defined as the angle between the principal plane 36 of the sapphire substrate 35 and the (01-12) plane of sapphire (denoted as “b” in the figure), similarly to the off-angle α, it should be noted that the off-angle β is in a direction of inclination different from that of the off-angle α by 90°. Whichever the sign of β is, there is no difference in the range specified in the present invention, and therefore it is not necessary to specify the sign of the angle. Therefore, it is described in terms of absolute value |β| in this specification.

The sapphire substrate 35 has off-angle α within the range described above, and the off-angle β in a range of 0°≦β≦0.05°. The reason for setting the off-angle β within the range described above is that |β| larger than 0.05° may result in lower surface smoothness of the crystal grown on the principal plane 12 of the sapphire substrate 11.

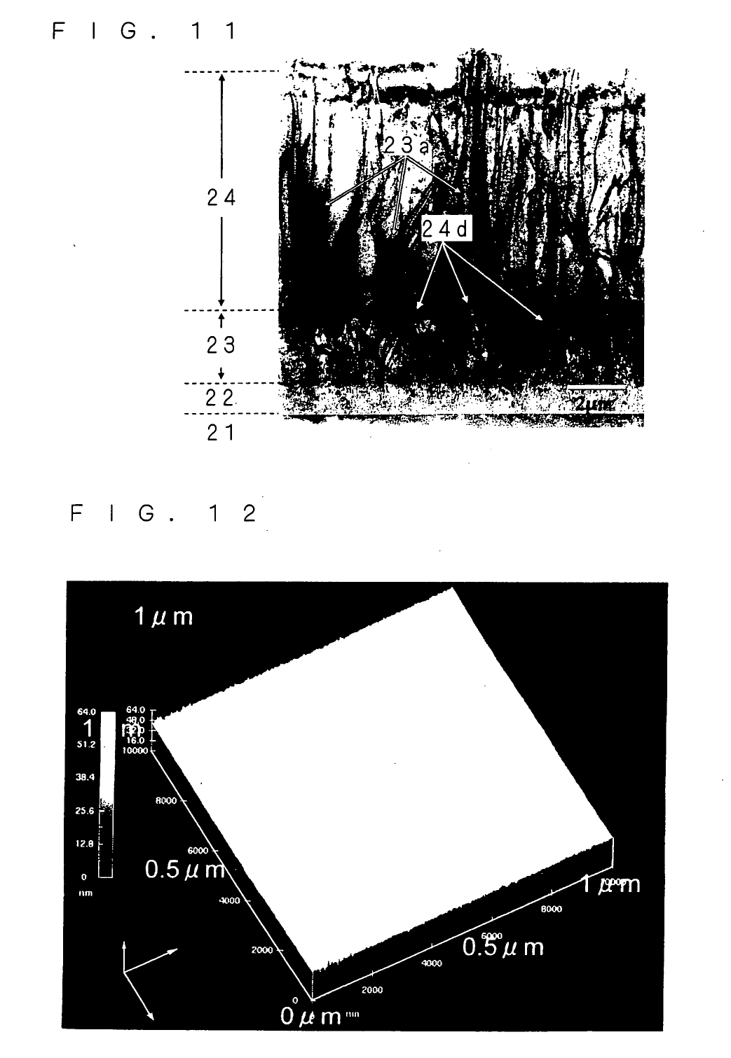

FIG. 9 is a perspective view showing the crystal orientation of the sapphire substrate 35 and the off-angle. Letter r in FIG. 9 denotes [01-12], while the off-angles α and β of the (01-12) plane are indicated as the off-angles of [01-12].

FIG. 10 is a sectional view showing an example of light emitting device that uses the sapphire substrate 35. An AlN layer 41, an undoped GaN layer 42, a GaN/GaInN active layer 44 having multiple quantum well structure, a p-type Al_{0.2}Ga_{0.8}N layer 45, a p-type Al_{0.07}Ga_{0.93}N cladding layer 46 and a p+ type GaN layer 47 are formed successively on the principal plane 36 of the sapphire substrate 35. By using the sapphire substrate 35 of which off-angle of the principal plane is strictly defined as described above, the light emitting device structure 40 oriented in [11-20] on the principal plane can be smoothed with a conventional thickness of not less than 0.5 μm and not more than 0.8 μm. That is, crystal orientation of the sapphire substrate 35 is strictly defined by setting the off-angle α within a narrow range and setting the off-angles β within a specified range, thereby making it possible to obtain a smooth surface without adjusting the light emitting device structure during the process of epitaxial growth of the nitride semiconductor.

Smoothness of the epitaxially grown nitride semiconductor may be evaluated in terms of arithmetic mean surface roughness measured by using an atomic force microscope (AFM). The surface roughness must be within 10 nm in terms of root mean square surface roughness. A light emitting device constituted from light emitting device structure that is not smoothed cannot produce high luminance.

The light emitting device structure 40 may be light emitting device structure in general that is constituted from nitride semiconductors represented by AlₓGa_{1-x-y}In_{y}N (0≦x, 0≦y, x+y≦1) and includes at least an n-type cladding layer, an active layer and a p-type cladding layer. There is no restriction on the light emitting device structure, since the effect of smoothing the surface is achieved by using the sapphire substrate described above.

Now the present invention will be described below in more detail by way of examples and comparative examples, though it is understood that the examples are not intended to limit the present invention.

### EXAMPLES

### Example I

The epitaxial substrate was made as an example of the first embodiment. The MOVPE method was employed as the growing method, and the sapphire substrate that the off-angle α toward the (0001) plane was set to 1.0° was used as the semiconductor growing substrate 11.

A base layer 121 was formed from AlN to a thickness of 200 nm on the sapphire substrate at a temperature of 1100° C., followed by the growth of a channel layer 122 formed from GaN to a thickness of 50 nm at a temperature of 1100° C.

Then a barrier layer 123 was formed from AlGaN having AlN molar ratio of 0.25 to a thickness of 27 nm on the sapphire substrate at a temperature of 1000° C.

The barrier layer 123 was subjected to modulated doping, so as to form an undoped spacer 425 having thickness of 7 nm and an electron feeding layer 426 having thickness of 20 nm doped with silicon (not shown), thereby to obtain the epitaxial substrate 1. Through measurement by X-ray diffraction, it was confirmed that C axis of the stacked layer structure 12 was within the stacked layer structure 12 and parallel to the principal plane of the sapphire substrate 11 .

The epitaxial substrate 1 was used to make the FET 3 shown in FIG. 3. After forming a mask using photolithography process, dry etching with chloride gas was carried out to a depth of 60 nm for the purpose of isolation of device. Then the source electrode 31 and the drain electrode 32 were formed by deposition of Ti/Al/Ti to thickness of 30/100/20 nm by electron beam vapor deposition, followed by heat treatment at a temperature of 850° C. for 90 seconds in nitrogen atmosphere. Then the gate electrode 33 was formed by deposition of Ni/Au to thickness of 20/80 nm.

The FET 3 shown in FIG. 3 was made as described above. The FET was of enhancement type in which the drain current flows when gate bias is applied.

Surface roughness of the epitaxial substrate 1 was measured by means of AFM. Measured value of surface roughness was 7 nm. No crack was observed on the surface of the epitaxial substrate 1.

### Example II

Similarly to Example I, the epitaxial substrate was made. The base layer 121 was grown at a temperature of 1000° C. by using AlGaN having AlN molar ratio of 0.5 and film thickness of 200 nm. Then the channel layer 122 was grown from GaN to a thickness of 50 nm at a temperature of 1100° C. Next the barrier layer 127 was grown from AlGaN having AlN molar ratio of 0.25 to a thickness of 27 nm at a temperature of 1100° C.

The barrier layer 123 was subjected to modulated doping, so as to form an undoped spacer layer having thickness of 7 nm and an electron feeding layer 426 having thickness of 20 nm doped with silicon (not shown), thereby to obtain the epitaxial substrate 1. Through measurement by X-ray diffraction, it was confirmed that C axis d of the stacked layer structure 12 was parallel to the principal plane of the semiconductor growing substrate 11.

The epitaxial substrate 1 was used to make the FET 3 shown in FIG. 3 by a method similar to that of Example I. The FET was of enhancement type in which the drain current flows when gate bias is applied.

Surface roughness of the epitaxial substrate 1 was measured similarly to that of Example I. Measured value of surface roughness was 7 nm. No crack was observed on the surface of the epitaxial substrate 1.

### Examples II-1 Through 11, Comparative Examples II-1 and 2

Enhancement type FETs were made similarly to Example II under the conditions shown in Table 1, and were evaluated similarly to Example I. The results are shown in table 1, where A indicates no cracks observed, and B indicates existence of crack.

TABLE 1

| | | Molar ratio | Thickness | | |
|---|---|---|---|---|---|
| | Off- | of AlN in | of base | Surface | |
| | angle | base layer | layer | roughness | Crack |
| | deg | — | μm | nm | — |
| Example II-1 | 0.1 | 0.75 | 1 | 5 | ◯ |
| Example II-2 | 2 | 0.75 | 1 | 5 | ◯ |
| Example II-3 | 4 | 0.75 | 1 | 6 | ◯ |
| Example II-4 | 5 | 0.75 | 1 | 7 | ◯ |
| Example II-5 | 2 | 0.75 | 0.01 | 10 | ◯ |
| Example II-6 | 2 | 0.75 | 0.05 | 3 | ◯ |
| Example II-7 | 2 | 0.75 | 2 | 3 | ◯ |
| Example II-8 | 2 | 0.75 | 3 | 4 | Δ |
| Example II-9 | 2 | 0.5 | 1 | 6 | ◯ |
| Example II-10 | 2 | 0.4 | 1 | 8 | ◯ |
| Example II-11 | 2 | 1 | 1 | 2 | ◯ |
| Comp. Example | 0 | 0.75 | 1 | 20 | ◯ |
| II-1 | | | | | |
| Comp. Example | 6 | 0.75 | 1 | 20 | ◯ |
| II-2 | | | | | |

As indicated by Comparative Examples II-1 and II-2, use of the sapphire substrate 11 having off-angle α of 0° or 6° resulted in rough surface.

In Examples II-1 through 4, small surface roughness was obtained with the sapphire substrate 11 having off-angle α in a range of 0°<α≦5°.

When the base layer 121 was formed to a thickness of 0.05 to 2 μm as in the cases of Examples II-6, 7, surface roughness could be kept small, but surface roughness showed a tendency to increase when the thickness was smaller than 0.05 μm as shown in Example II-5.

When the base layer 121 was formed to a thickness larger than 2 μm as in the case of Example II-8, cracks tend to be generated.

Comparison of Examples II-2, 9, 10, 11 for the purpose of determining the optimum molar ratio of AlN in the base layer showed a tendency of surface roughness becoming poorer when the molar ratio of AlN is lower than 0.5 as indicated by Example 9.

### Example III

Now examples of the second embodiments will be described. The R-plane sapphire substrate was used as the semiconductor growing substrate 21 to grow layers by the MOVPE method as shown in FIG. 4.

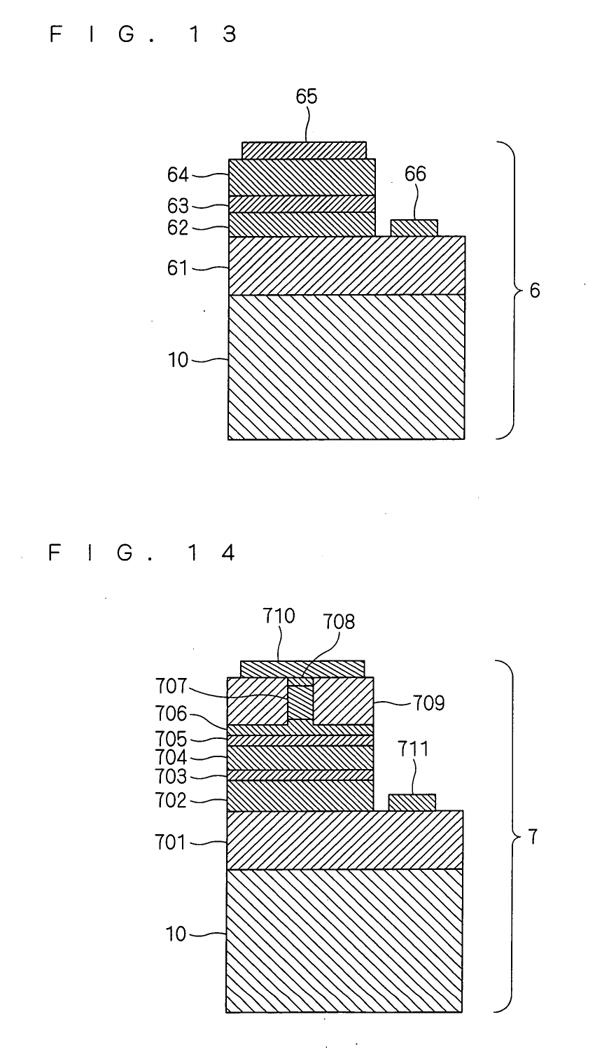

The base layer 22 was formed from AlN to a thickness of 100 nm at a temperature of 1100° C., followed by the formation of the first layer 23 from Al_{0.5}Ga_{0.5}N at a temperature of 850° C., thereby to generate the irregular surface 23a. At this time, since AlN has a lattice constant larger than that of Al_{0.5}Ga_{0.5}N, the first layer 23 receives strain from the base layer 22. Then the second layer 24 was formed from GaN to a thickness 3 μm so as to fill in the irregularity 23a, with the V/III ratio set to 300 and at a growing temperature of 950° C. FIG. 11 is a transmission electron microscope photograph of this sample. The irregular surface 23a was principally triangular distributed broadly over a range from 500 nm to 2 μm. The density of threading dislocations and density of stacking faults 24d due to a difference in the lattice constant between the R-plane sapphire substrate 21 and the base layer 22 are deflected sideways by the irregularity 23a and the lateral growth of the second layer 24 grown thereon resulted in density of threading dislocations and density of stacking faults of 5×10⁸/cm² and 5×10⁴/cm respectively, showing a significant decrease in density of stacking faults compared to 2×10⁹/cm² and 2×10⁵/cm of the prior art. As indicated by the atomic microscope observation shown in FIG. 12, the epitaxial substrate 10 having very smooth surface was obtained. Surface roughness was 0.2 nm in terms of RMS.

When the conditions of growing the second layer on the first layer were set to 1100° C. for growing temperature and 1000 for the V/III ratio, irregularity of the top surface of the first layer was not filled in by the second layer, resulting in very large surface roughness of 0.2 nm in terms of RMS. As a result, trouble was encountered in the photolithography process due to the surface irregularity, thus making it impossible to manufacture the semiconductor device.

### Examples III-1 Through 4, Comparative Examples III-1 and 2

In Example III, the following experiments were conducted in order to evaluate the surface smoothness and density of stacking faults with varying irregularity 23a, while varying the surface irregularity 13a of the first layer 1 made of Al_{0.5}Ga_{0.5}N to various levels. Then the second layer was formed from GaN under the same conditions. The sample was observed under a transmission electron microscope to measure the distribution of periods the surface irregularity, density of threading dislocations and density of stacking faults. The results are shown in Table 2.

TABLE 2

| | | | | Density of | Density of |
|---|---|---|---|---|---|
| | | | RMS surface | threading | stacking |
| | | | roughness | dislocations | faults |
| | | | (nm) | (/cm²) | (/cm) |
| (a) | Comparative | Irregularity | 0.2 | 5 × 10⁹ | 3 × 10⁵ |
| | Example | with periods | | | |
| | III-1 | less than | | | |
| | | 10 nm | | | |
| (b) | Example | Irregularity | 0.2 | 9 × 10⁸ | 8 × 10⁴ |
| | III-1 | with periods | | | |
| | | ranging from | | | |
| | | 10 nm to | | | |
| | | 100 nm | | | |
| (c) | Example | Irregularity | 0.2 | 7 × 10⁸ | 7 × 10⁴ |
| | III-2 | with periods | | | |
| | | ranging from | | | |
| | | 100 nm to | | | |
| | | 1 μm | | | |
| (d) | Example | Irregularity | 0.3 | 5 × 10⁸ | 7 × 10⁴ |
| | III-3 | with periods | | | |
| | | ranging from | | | |
| | | 1 μm to | | | |
| | | 10 μm | | | |
| (e) | Example | Irregularity | 1.0 | 5 × 10⁸ | 7 × 10⁴ |
| | III-4 | with periods | | | |
| | | ranging from | | | |
| | | 10 μm to | | | |
| | | 20 μm | | | |
| (f) | Comparative | Irregularity | 100.0 | 5 × 10⁸ | 7 × 10⁴ |
| | Example | with periods | | | |
| | III-2 | larger than | | | |
| | | 20 μm | | | |

Under the conditions (a) through (e) (Examples III-1 through 4 and Comparative Example III-1), the second layer showed surface roughness of 1 nm or less in terms of RMS that enabled it to manufacture the semiconductor device. Under the condition (f) (Comparative Example III-2), irregularity cannot be sufficiently filled in and resulted in a very large surface roughness of 100 nm in terms of RMS.

The density of threading dislocations was reduced to an order of 10⁸/cm² under the conditions (b) through (f) (Examples III-1 through 4 and Comparative Example III-2), but remained on an order of 10⁹/cm² under the condition (a) (Comparative Example III-1). The density of stacking faults was also reduced similarly to an order of 10⁴/cm under the conditions (b) through (f) (Examples III-1 through 4 and Comparative Example III-2), but remained on an order of 10⁵/cm under the condition (a) (Comparative Example III-1). Thus it was found that the period of surface irregularity of the first layer 1 may be in a range from 10 nm to 10 μm as in the cases of conditions (b) through (e) (Examples III-1 through 4).

### Examples III-5 Through 8, Comparative Examples III-3 and 4

Similarly to Examples III-1 through 4 and Comparative Examples III-1 and 2, distribution of height of the surface irregularity, density of threading dislocations and density of stacking faults were evaluated in Example III. The results are shown in Table 3.

TABLE 3

| | | | | Density of | Density of |
|---|---|---|---|---|---|
| | | | RMS surface | threading | stacking |
| | | | roughness | dislocations | faults |
| | | | (nm) | (/cm²) | (/cm) |
| (g) | Comparative | Irregularity | 0.2 | 5 × 10⁹ | 3 × 10⁵ |
| | Example | with height | | | |
| | III-3 | less than | | | |
| | | 0 nm | | | |
| (h) | Example | Irregularity | 0.2 | 9 × 10⁸ | 8 × 10⁴ |
| | III-5 | with height | | | |
| | | ranging from | | | |
| | | 10 nm to | | | |
| | | 100 nm | | | |
| (i) | Example | Irregularity | 0.2 | 7 × 10⁸ | 7 × 10⁴ |
| | III-6 | with height | | | |
| | | ranging from | | | |
| | | 100 nm to | | | |
| | | 1 μm | | | |
| (j) | Example | Irregularity | 0.3 | 5 × 10⁸ | 7 × 10⁴ |
| | III-7 | with height | | | |
| | | ranging from | | | |
| | | 1 μm to | | | |
| | | 5 μm | | | |
| (k) | Example | Irregularity | 1.0 | 5 × 10⁸ | 7 × 10⁴ |
| | III-8 | with height | | | |
| | | ranging from | | | |
| | | 5 μm to | | | |
| | | 10 μm | | | |
| (I) | Comparative | Irregularity | 100.0 | 5 × 10⁸ | 7 × 10⁴ |
| | Example | with height | | | |
| | III-4 | larger than | | | |
| | | 10 μm | | | |

Under the conditions (g) through (k) (Examples III-5 through 8 and Comparative Example III-3), the second layer showed surface roughness of 1 nm or less in terms of RMS that enabled it to manufacture the semiconductor device. Under the condition (1) (Comparative Example III-4), irregularity cannot be sufficiently filled in and resulted in a very large surface roughness of 100 nm in terms of RMS. The density of threading dislocations was reduced to an order of 10⁸/cm² under the conditions (h) through (l) (Examples III-5 through 8 and Comparative Example III-4), but remained on an order of 10⁹/cm² under the condition (g) (Comparative Example III-3). The density of stacking faults was also reduced similarly to an order of 10⁴/cm under the conditions (h) through (l) (Examples III-5 through 8 and Comparative Example III-4), but remained on an order of 10⁵/cm under the condition (a) (Comparative Example 3). Thus it was found that height of surface irregularity of the first layer 1 may be in a range from 10 nm to 10 μm as in the cases of conditions (h) through (k) (Examples III-5 through 8).

### Example IV

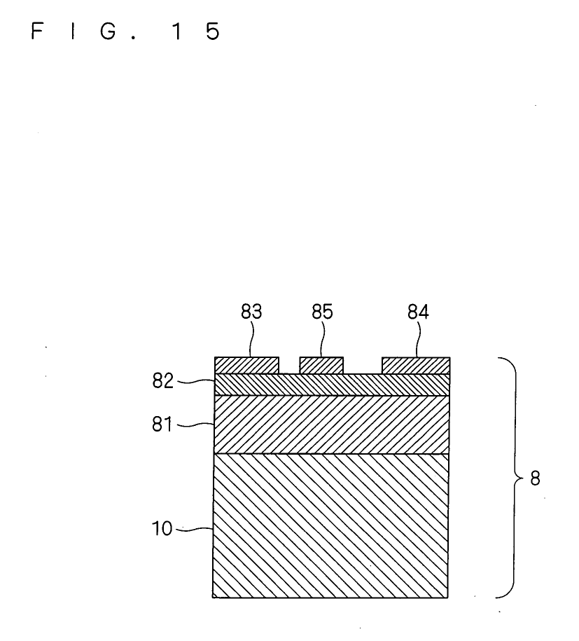

The epitaxial substrate 10 comprising the first layer having surface irregularity within the range of Example III was used to make a green light emitting diode operating at a wavelength of 520 nm shown in FIG. 13. An n-type cladding layer 61 made of GaN, an active layer 62 made of GaInN, a p-type cladding layer 63 made of AlGaN and a p-type contact layer 64 made of GaN were formed by MOVPE method on the epitaxial substrate 10. After partially exposing the n-type cladding layer 61 by dry etching, the p-side electrode 65 and the n-side electrode 66 were formed by electron beam vapor deposition, thereby to obtain the light emitting diode 6.

The light emitting diode showed an external quantum efficiency about 1.5 times higher than that of a light emitting diode of similar structure made by using an epitaxial substrate having such a structure as the heterojunction interface of the light emitting device structure is perpendicular on the C-plane sapphire substrate.

### Example V

The epitaxial substrate 10 was used to make a laser diode oscillating at a wavelength of 400 nm shown in FIG. 14. An n-type contact layer 701 made of GaN, an n-type cladding layer 702 made of AlGaN, an n-type guide layer 703 made of GaN, an active layer 704 made of GaInN, a p-type guide layer 705 made of GaN, a block layer 706 made of AlGaN, a p-type cladding layer 707 made of AlGaN and a p-type contact layer 708 made of GaN were formed by MOVPE method on the epitaxial substrate 10. After exposing the n-type contact layer 701 by dry etching, the p-type cladding layer was exposed to form a ridge structure. An insulation layer 709 was formed from SiO₂ so as to cover the side wall of the ridge structure, and the p-side electrode 710 and the n-side electrode 711 were formed by electron beam vapor deposition, thereby to obtain the laser diode 7.

The laser diode showed threshold current lower than that of a device made by using an epitaxial substrate having such a structure as the heterojunction interface is perpendicular to the C axis of the prior art.

### Example VI

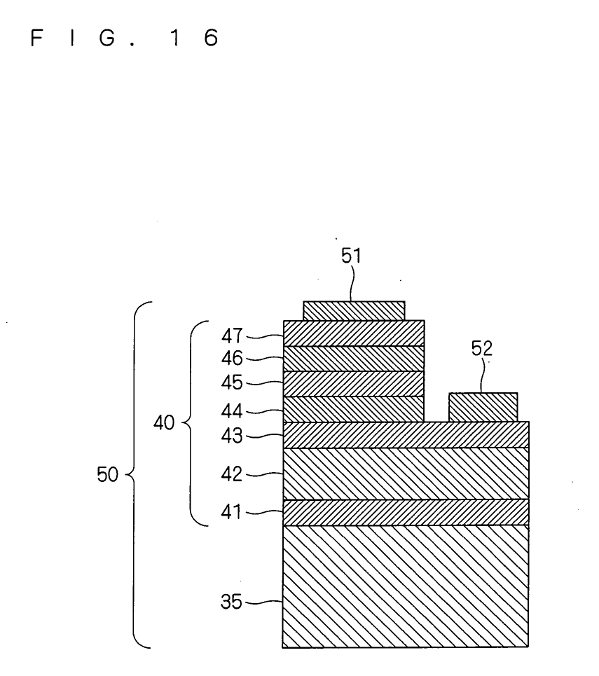

The epitaxial substrate 10 was used to make a field effect transistor 8 shown in FIG. 15. A channel layer 81 made of GaN and a barrier layer 82 made of AlGaN were formed successively by the MOVPE method. After carrying out isolation of device, a source electrode 83, a drain electrode 84 and a gate electrode 84 were formed by electron beam vapor deposition, thereby to obtain the field effect transistor 8.

Current did not flow between the source electrode 83 and the drain electrode 84 when the gate bias was zero. When +1 V of bias voltage was applied, current of 0.1 A/mm flowed. Thus the enhancement type operation that had been impossible in the past was obtained.

### Example VII

In Examples III through VI, after growing the first layer 13 having the condition of crystallinity such as the irregularity 13a described above, the second layer was grown thereon without taking sample out of the semiconductor growing apparatus. In Example VII, in contrast, the second layer 24 made of GaN was grown after growing the first layer and taking it out of the semiconductor growing apparatus and checking the irregularity 13a.

RMS surface roughness of the epitaxial substrate 10, density of threading dislocations and density of stacking faults showed similar values as those in Example III-1, even when the second layer 24 was grown after once taking out the sample. The light emitting diode 6 shown in FIG. 13, the laser diode 7 shown in FIG. 14 and the field effect transistor 8 shown in FIG. 15 were made similarly to Example III through VI, respectively. Thus the semiconductor devices having characteristics similar to those of Example III through VI were obtained.

### Example VIII

In Examples III through VII, the first layer 23 having the condition of crystallinity such as the irregularity 23a was grown. In Example VIII, in contrast, after growing the first layer, the sample was taken out of the semiconductor growing apparatus and the first layer was intentionally processed with dry etching to obtain the surface irregularity 23a, and then the second layer was grown.

RMS surface roughness of the epitaxial substrate 10, density of threading dislocations and density of stacking faults showed similar values as those in Example III-1, even when the second layer 24 was grown after once taking out the sample and intentionally processing the first layer to obtain the surface irregularity 23a. The light emitting diode 6 shown in FIG. 13, the laser diode 7 shown in FIG. 14 and the field effect transistor 8 shown in FIG. 15 were made similarly to Example III through VI, respectively. Thus the semiconductor devices having characteristics similar to those of Examples III through VI were obtained.

### Example IX

In Examples III through VIII, the second layer 24 was grown from GaN. In Example IX, in contrast, the second layer 24 made of Al_{0.2}Ga_{0.8}N was grown after growing the first layer 23 made of Al_{0.5}Ga_{0.5}N so as to obtain the surface irregularity 23a described above.

RMS surface roughness of the epitaxial substrate 10, density of threading dislocations and density of stacking faults showed similar values as those in Example III-1, also when the second layer 14 made of Al_{0.2}Ga_{0.8}N was grown. The light emitting diode 6 shown in FIG. 13, the laser diode 7 shown in FIG. 14 and the field effect transistor 8 shown in FIG. 15 were made similarly to Example III through VI, respectively.

The devices had other layers made of GaN (the n-type cladding layer 61 in the case of the light emitting diode, the n-type cladding layer 71 in the case of the laser diode and the channel layer 81 in the case of the field effect transistor) formed on the second layer 24.

Thus the semiconductor devices having characteristics similar to those of Example III through VI were obtained.

### Example X

While the base layer 22 was used in Examples III through IX, the first layer 23 was grown directly on the R-plane sapphire substrate 21 without using the base layer 22 in this example.

First, the first layer made of AlN was grown directly on the R-plane sapphire substrate 21 by the MOVPE method, and surface irregularity 23a in a range from 10 nm to 20 μm in period and in a range from 10 nm to 10 μm in height was observed depending on the growing conditions. Then the second layer was grown from GaN so as to fill in the surface irregularity 23a, thereby to obtain the epitaxial substrate 20.

The epitaxial substrate 20 showed RMS surface roughness of the epitaxial substrate 10, density of threading dislocations and density of stacking faults of similar values as those of the epitaxial substrate 10 in Examples 1 through 4. The light emitting diode 6, the laser diode 7 and the field effect transistor 8 were made similarly to Examples III through VI, respectively. Thus the semiconductor devices having characteristics similar to those of Example III through VI were obtained.

### Example XI

Now examples of the third embodiments will be described while making reference to FIG. 10. A light emitting device structure 40 was epitaxially grown. As a growing method, the MOVPE method was used. As a semiconductor growing substrate 35, the sapphire substrate that the off-angle α inclining toward the (0001) plane was set to −0.5° was used. The AlN layer 41 (200 nm), the GaN layer 42 (2 μm), the n-type cladding layer 43 (500 nm), the GaN/GaInN active layer 44 (30 nm) having multiple quantum well structure, the p-type Al_{0.2}Ga_{0.8}N layer 45 (2 nm), the p-type Al_{0.07}Ga_{0.93}N cladding layer 46 (3 nm) and the p+ type GaN layer 47 (3 nm) were formed successively on the sapphire substrate, thereby to make the light emitting device structure 40. The n-type layers were doped with silicon, and the p-type layers were doped with magnesium. Every layer that constitutes the light emitting device structure was not larger than 3 μm in thickness, making it suitable for volume production.

Growing temperatures of the layers were set so as not to affect the characteristics of the epitaxial substrate such as composition, crystallinity, surface roughness and electric properties.

Through measurement by X-ray diffraction, it was confirmed that the light emitting device structure 40 was oriented in [01-12] direction.

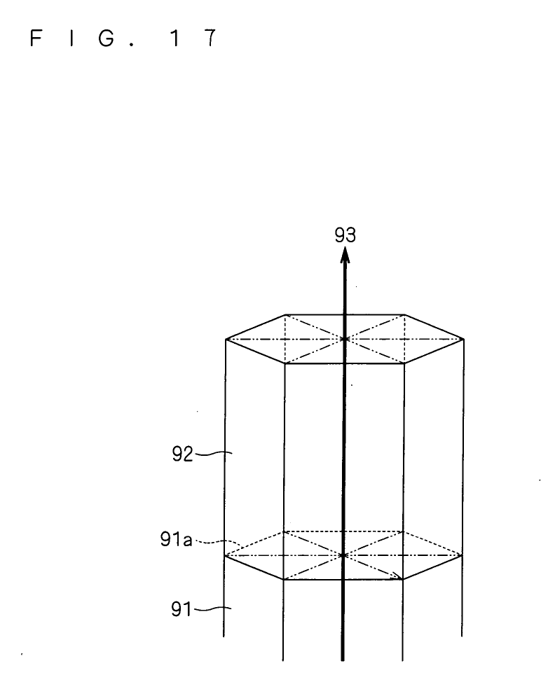

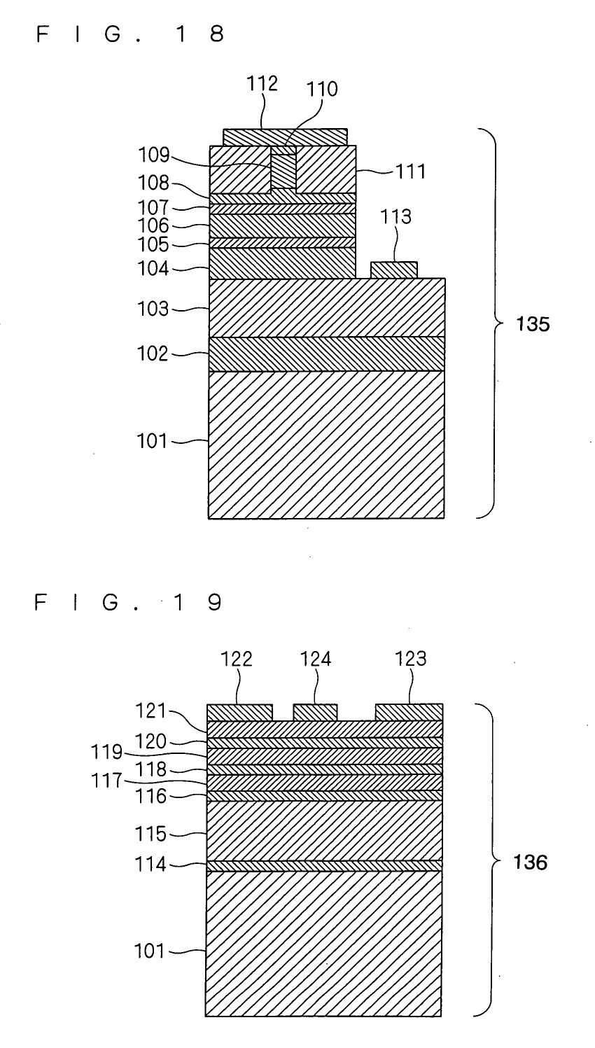

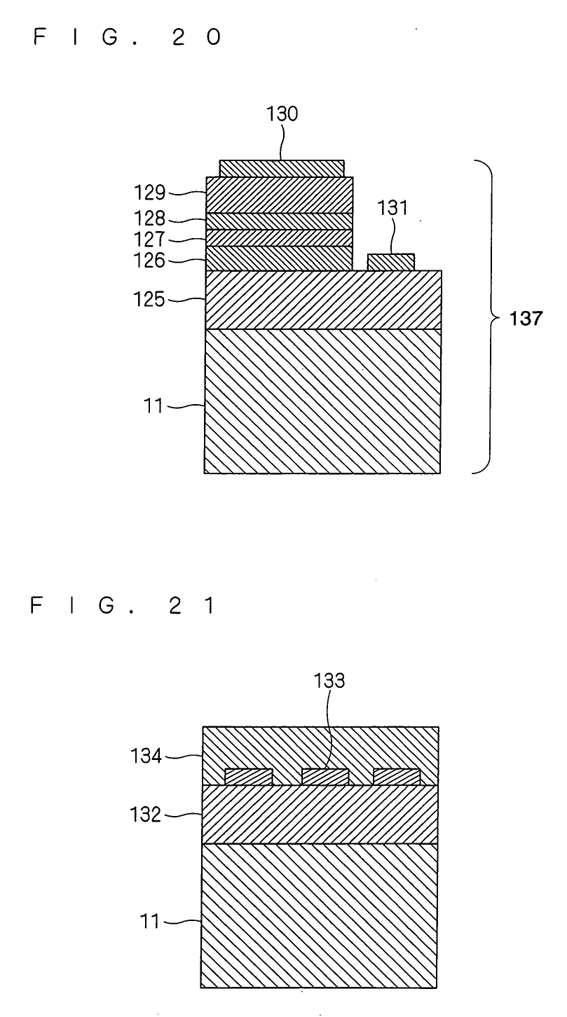

A light emitting device 50 as shown in FIG. 16 was produced. A mask was formed by photolithography, and dry etching was carried out using chloride gas. Depth of etching was controlled so that etching would be stopped amid the n-type cladding layer 43.

A p-side ohmic electrode 51 was formed by deposition of Ni/Au to thickness of 20/80 nm, and an n-side ohmic electrode 52 was formed by deposition of Ti/Al/Ti to thickness of 30/100/20 nm, thereby to obtain the light emitting device 50.

The light emitting device 50 was a blue light emitting device having peak wavelength of 450 nm, and showed higher luminance than in the case of orienting the light emitting device structure similar to that described above in [0001] direction.

### Examples XII-1 Through 6, Comparative Examples XII-1 and 2

Examples XII-1 through 6, Comparative Examples XII-1 and 2 were made similarly to Example XI while varying the conditions as shown in Table 4, and were evaluated.

The off-angle β was fixed at 0° and the off-angle α was changed as in Comparative Examples XII-1 and 2. In case the sapphire substrate 35 having the principal plane in (01-12) plane of a being −0.2° and β being −0.8°, the light emitting device structure 4 showed larger surface roughness.

In Examples XII-1 through 3, surface roughness was kept small when the off-angle α was in the range of −0.75°≦α≦−0.25°.

In case the off-angle α was fixed at −0.5° and the off-angle β was changed as in Examples XII-4 through 6, surface roughness was kept small when |β| was less than 0.5°.

TABLE 4

| | Off-angle | Off-angle | Surface |
|---|---|---|---|
| | α | \|β\| | roughness |
| | deg | deg | nm |
| Example XII-1 | −0.5 | 0 | 5 |
| Example XII-2 | −0.3 | 0 | 6 |
| Example XII-3 | −0.7 | 0 | 6 |
| Example XII-4 | −0.5 | 0.06 | 15 |
| Example XII-5 | −0.5 | 0.04 | 8 |
| Example XII-6 | −0.5 | 0.02 | 7 |
| Comparative | −0.2 | 0 | 20 |
| Example XII-1 | | | |
| Comparative | −0.8 | 0 | 20 |
| Example XII-2 | | | |

1. A sapphire substrate of which principal plane for growing nitride semiconductor is inclined from (01-12) plane toward (0001) plane by an off-angle α that is in a range of 0°<α<5°.

2. An epitaxial substrate for manufacturing a field effect transistor that has heterojunction structure comprising at least a channel layer of gallium nitride or gallium indium nitride and a barrier layer of aluminum gallium nitride, that are formed successively on the principal plane of the sapphire substrate,
wherein the principal plane of said sapphire substrate is inclined from (01 12) plane toward (0001) plane by an off-angle α that is in a range of 0°<α<5°.

3. The epitaxial substrate according to claim 2, wherein a base layer of aluminum gallium nitride AlxGa1-xN of which molar ratio x of aluminum nitride is in a range of 0.5<x<1.0 is grown directly on said sapphire substrate.

4. The epitaxial substrate according to claim 3, wherein the thickness of said base layer is in a range from 0.05 to 2.0 μm.

5. A semiconductor device that uses the epitaxial substrate according to claim 2 or 3.

6. An epitaxial substrate comprising a sapphire substrate having the principal plane in the (01-12) plane and at least a first layer and a second layer that are made of nitride semiconductors of different compositions formed in this order on the substrate, wherein
the sectional plane in the top surface of said first layer has surface irregularity from 10 nm to 20 μm in period and 10 nm to 10 μm in height, and the top surface of said second layer has root mean square surface roughness (RMS) of less than 10 nm.

7. The epitaxial substrate according to claim 6, wherein (01-12) plane of said sapphire substrate is inclined by an off-angle α of±5 degrees except for 0 degree.

8. The epitaxial substrate according to claim 6, wherein said first layer is made of aluminum gallium nitride AlxGa1-xN (0<x<1).

9. The epitaxial substrate according to claim 6, wherein said second layer is made of gallium nitride.

10. The epitaxial substrate according to claim 6 that has a semiconductor device structure on said second layer.

11. A semiconductor device that uses the epitaxial substrate according to claim 5.

12. A method for manufacturing the epitaxial substrate according to claim 6, which comprises the steps of:
growing the first layer on said sapphire substrate so that the lower surface of said first layer receives a strain caused by lattice mismatch directly or indirectly from said sapphire substrate, thereby to form the sectional plane in the top surface of said first layer with surface irregularity from 10 nm to 20 μm in period and from 10 nm to 10 μm in height; and
growing said second layer on the first layer, that are carried out in this order.

13. A method for manufacturing the epitaxial substrate according to claim 6, which comprises the steps of:
growing said first layer on the sapphire substrate having the principal plane in the R plane;
applying post-processing to form the sectional plane in the top surface of said first layer with surface irregularity from 10 nm to 20 μm in period and from 10 nm to 10 μm in height; and
growing said second layer on the first layer, that are carried out in this order.

14. A sapphire substrate of which principal plane is inclined from (01-12) plane toward (0001) plane by an off-angle α that is in a range of −0.75°<α<−0.25°.

15. A sapphire substrate of which principal plane is inclined from (01-12) plane toward (0001) plane by an off-angle α and, at the same time, inclined by an off-angle of β in a direction perpendicular to this direction, the angles being in ranges of −0.75°<α<−0.25° and 0°<|β↑<0.05°.

16. A light emitting device comprising;
the sapphire substrate according to claim 14 or 15; and
a light emitting device structure that is provided on the principal plane of said sapphire substrate, made of nitride semiconductor represented by AlxGa1 x yInyN (0<x, 0<y, x+y<1) and includes at least an n-type cladding layer, an active layer and a p-type cladding layer.

17. The light emitting device according to claim 16, wherein the thickness of said light emitting device structure is in a range from 0.5 μm to 8 μm.

18. A semiconductor device that uses the sapphire substrate according to claim 14 or 15.
